(19) United States
(12) Patent Application Publication
(10) Pub. No.: US 2014/0184782 A1
(43) Pub. Date: Jul. 3, 2014

(54) SYSTEM OF MEASURING WARPAGE AND METHOD OF MEASURING WARPAGE

(71) Applicant: Samsung Electro-Mechanics Co., Ltd., Suwon-si (KR)

(72) Inventors: Seung Wan WOO, Suwon-si (KR); Po Chul KIM, Suwon-si (KR); Young Nam HWANG, Suwon-si (KR); Kyung Ho LEE, Suwon-si (KR); Suk Jin HAM, Suwon-si (KR)

(73) Assignee: SAMSUNG ELECTRO-MECHANICS CO., LTD., Suwon-si (KR)

(21) Appl. No.: 14/142,714

(22) Filed: Dec. 27, 2013

(30) Foreign Application Priority Data
Dec. 28, 2012 (KR) 10-2012-0156854

(51) Int. Cl. H01L 21/66; H05K 1/02

(52) U.S. Cl. CPC H01L 22/12; H05K 1/0201
USPC 348/87

(57) ABSTRACT

Disclosed herein are a system for measuring a warpage and a method for measuring a warpage. The system for measuring a warpage includes: a heating plate portion heating the sample; and a reference gating portion disposed between the sample and the camera so as to be spaced apart from the sample by a predetermined distance, wherein the reference grating portion includes a plurality of wires that are each spaced apart from each other by a predetermined interval, thereby accurately measuring the warpage without being affected by the fume generated from the sample.

### CROSS REFERENCE(S) TO RELATED APPLICATIONS

This application claims the benefit under 35 U.S.C. Section 119 of Korean Patent Application Serial No. 10-2012-0156854 entitled “System of Measuring Warpage and Method of Measuring Warpage” filed on Dec. 28, 2012, which is hereby incorporated by reference in its entirety into this application.

### BACKGROUND OF THE INVENTION

1. Technical Field

The present invention relates to a system of measuring a warpage and a method of measuring a warpage.

2. Description of the Related Art

Recently, a demand for miniaturization and slimness of electronic products has increased. In order to meet the demand, attempts to make a substrate used as main parts of various electronic products smaller and thinner has continuously conducted. Further, in order to implement high performance of electronic products, technologies for mounting active devices such as integrated circuit chips with high integration, and the like, and passive devices such as MLCC, inductor, and the like, in the inside or the outside of the substrate have been proposed.

Therefore, recently released package substrates have a duplex structure and the inside and outside of the package substrate are formed with numerous micro circuit patterns and various electronic parts are embedded in the inside thereof or mounted on a surface thereof.

However, the complicated and slim package substrate products have reduced reliability due to a bending deflection phenomenon, that is, a warpage phenomenon according to the increase in temperature.

Therefore, a study for developing a technology of reducing the warpage, a technology of measuring how much the warpage is generated when the substrate is exposed to the high temperature environment, and the like, have been conducted in various angles.

A representative method of the methods of measuring the warpage of the substrate may include a shadow moiré method introduced in Patent Document 1.

FIG. 1 is a diagram for describing a general measuring principle according to the related art that measures warpage based on the shadow moiré method and FIG. 2 is a diagram schematically illustrating a fringe image.

Referring to FIGS. 1 and 2, an image reflected from a surface of a sample 2 by irradiating light using a light source 3 in the state in which a reference grating 1 arranged on a transparent quartz panel at a predetermined interval and rendered as a reference line is disposed on a measuring sample 2 is acquired by a camera 4. In this case, the acquired image is formed with a fringe as illustrated in FIG. 2, such that it can measure how much the sample is warped based on the analysis of the fringe.

Meanwhile, in order to acquire the fringe image by using the shadow moiré method, light needs to be diffused reflection from the surface of the sample.

Therefore, a sample pre-treating process is required in order to make the surface of the sample as the diffused reflection surface, which is performed by a process of thinly applying white spray on the surface of the sample.

However, the temperature of the sample is increased to about 260° C. by a heating plate 5, and the like, at the time of measuring the high temperature warpage. In this case, a fume is generated from a white spray material due to the high temperature.

The surface of the reference grating 1 is polluted due to the fume and thus, a contrast is the measured image is remarkably degraded, causing a problem in that the warpage cannot be accurately analyzed.

### RELATED ART DOCUMENT

### Patent Document

(Patent Document 1) U.S. Pat. No. 7,230,722

### SUMMARY OF THE INVENTION

An object of the present invention is to provide a system for measuring a warpage capable of preventing a reference grating portion from being polluted due to fume generated from a sample.

Another object of the present invention is to provide a method for measuring a warpage capable of reducing a measuring error of a warpage due to a fume generated from a sample.

According to an exemplary embodiment of the present invention, there is provided a system of measuring a warpage of a sample by analyzing an image photographed by a camera acquiring light emitted from a light source and reflected from a surface of the sample and arriving through a reference grating portion, the system including: a heating plate portion heating the sample; and a reference gating portion disposed between the sample and the camera so as to be spaced apart from the sample by a predetermined distance, wherein the reference grating portion includes a plurality of wires that are each spaced apart from each other by a predetermined interval.

The reference grating portion may include: a first support bar to which ends of the plurality of wires are fixed; and a second support bar to which other ends of the plurality of wires are fixed, wherein the first support bar may be connected with a tension maintaining portion maintaining a tension of the plurality of wires.

The tension maintaining portion may include a driving unit providing attractive force to the first support bar.

The tension maintaining portion may further include a tension measuring portion coupled with the first support bar and measuring force moving the first support bar in a direction of the second support bar, wherein the driving unit may be connected with the tension measuring portion to start to drive when the tension measured by the tension measuring portion is less than a reference value.

The tension maintaining portion may be a spring.

The plurality of wires may be formed of a material having a coefficient of thermal expansion less than 15 ppm/° C.

According to another exemplary embodiment of the present invention, there is provided a system for measuring a warpage, including: a light source irradiating light to be reflected from a surface of a sample of which the warpage is measured; a heating plate portion having the sample disposed thereon and emitting heat; a reference grating portion spaced apart from the sample by a predetermined distance and transmitting light reflected from the surface of the sample; a camera acquiring light transmitting the reference grating portion to photograph an image; a server analyzing the image photographed by the camera to calculate the warpage of the sample; and a control unit provided with an intake portion removing a fume generated from the sample, wherein the reference grating portion includes a plurality of wires that are each spaced apart from each other by a predetermined interval.

The reference grating portion may further include a first support bar to which ends of the plurality of wires are fixed; a second support bar to which other ends of the plurality of wires are fixed; and a driving unit providing attractive force to the first support bar.

The reference grating portion may further include a tension measuring portion coupled with the first support bar and measuring force moving the first support bar in a direction of the second support bar, wherein the driving unit may be connected with the tension measuring portion to start to drive when the tension measured by the tension measuring portion is less than a reference value.

The reference grating portion may further include a tension measuring portion coupled with the first support bar to measure force moving the first support bar in a direction of the second support bar and provide the measured force to the control unit, and the control unit may include a tension control unit that is connected with the driving unit to generate a control signal driving the driving unit when the tension measured by the tension measuring portion is less than a reference value.

The control unit may further include a temperature control unit that is connected with the heating plate portion to control a temperature of the heating plate portion.

The control unit may further include a distance control unit connected with the reference grating portion to control a distance between the reference grating portion and the heating plate portion.

According to still another exemplary embodiment of the present invention, there is provided a method for measuring a warpage of a sample by analyzing an image photographed by a camera acquiring light emitted from a light source and reflected from a surface of a sample and transmitting between a plurality of wires spaced apart from each other by a predetermined interval, wherein the image is photographed while a tension of the plurality of wires is maintained above a predetermined reference value.

### BRIEF DESCRIPTION OF THE DRAWINGS

FIG. 1 is a diagram for describing a general measuring principle according to the related art for measuring a warpage using a shadow moiré method.

FIG. 2 is a diagram schematically illustrating a fringe image.

FIG. 3 is a diagram schematically illustrating a system for measuring a warpage according to an embodiment of the present invention.

FIG. 4 is a diagram schematically illustrating a control unit of FIG. 3.

FIG. 5 is a cross-sectional view illustrating main parts of a system for measuring a warpage according to an embodiment of the present invention.

FIG. 6 is a plan view schematically illustrating a reference grating portion of the system for measuring a warpage according to the embodiment of the present invention.

FIG. 7 is a diagram for describing a principle of removing a fume of the system for measuring a warpage according to the exemplary embodiment of the present invention.

FIG. 8 is a diagram schematically illustrating a fringe image acquired in a state in which the reference grating is not polluted.

FIG. 9 is a diagram schematically illustrating a fringe image acquired in a state in which the reference grating is polluted.

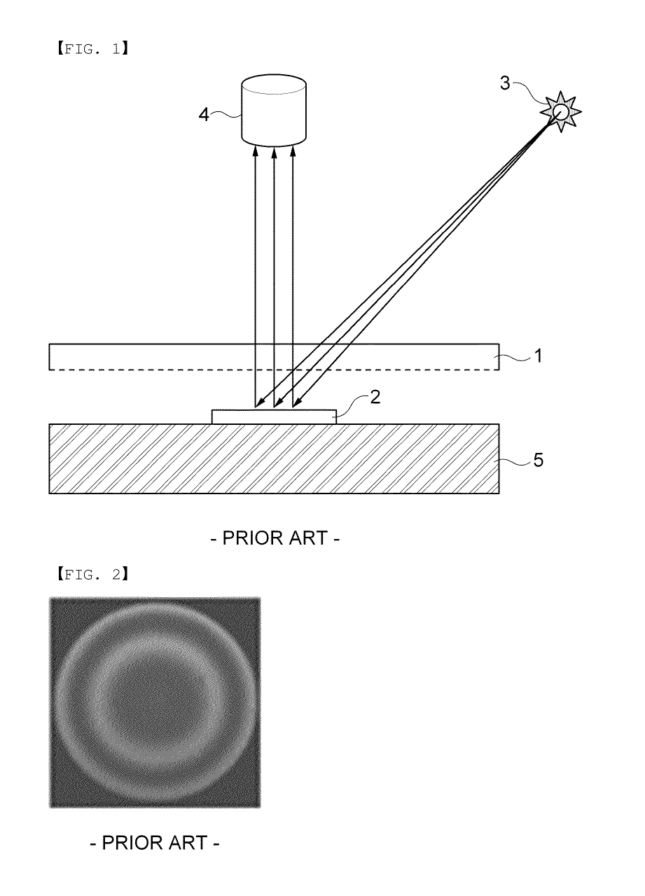

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the description denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, size of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth” and the like, if any, will be used to distinguish similar components from each other and be used to describe a specific sequence or a generation sequence, but is not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein it not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, are not necessarily to indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

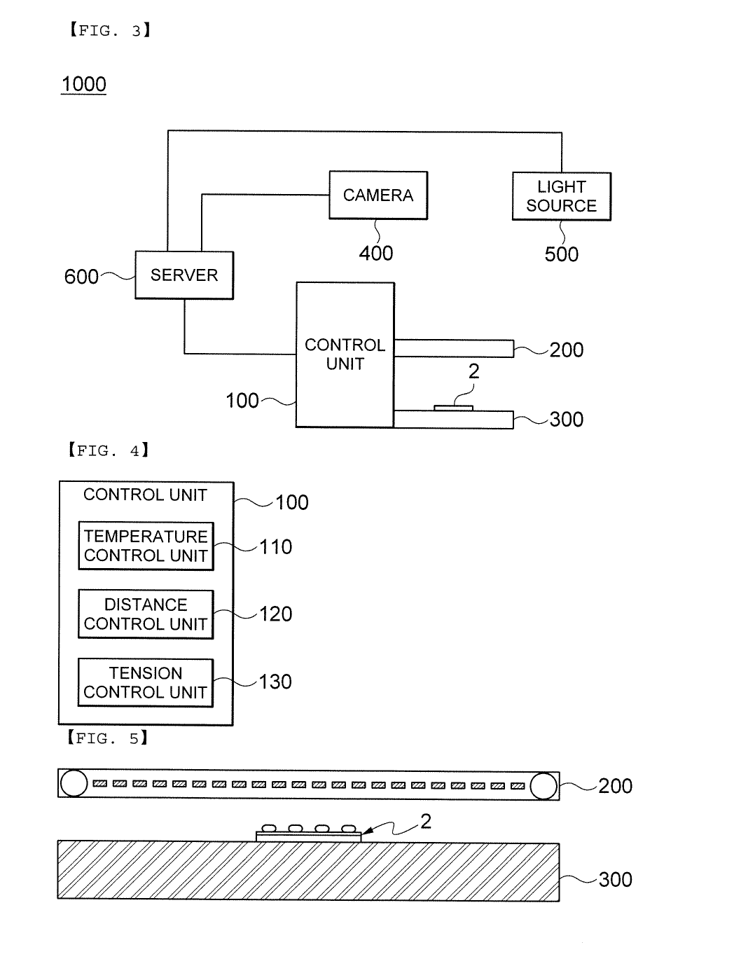

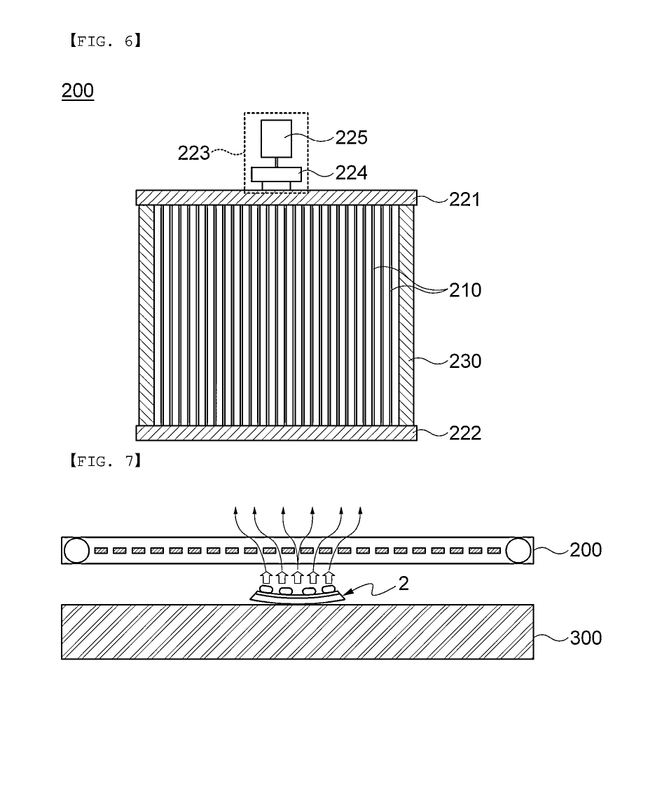

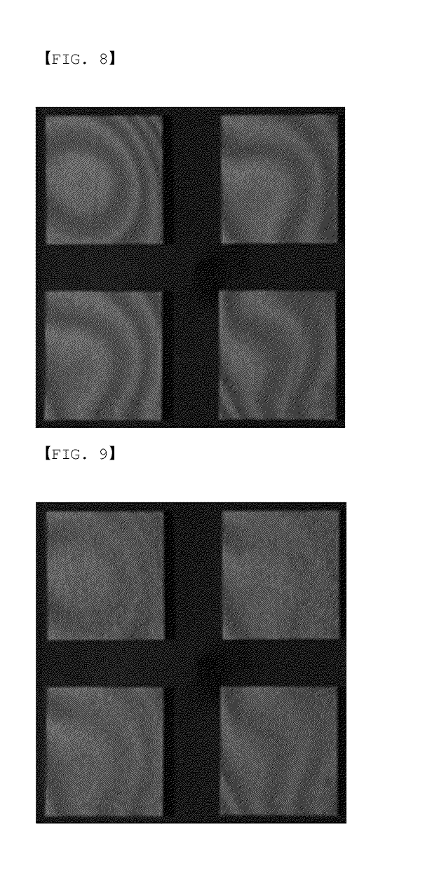

FIG. 3 is a diagram schematically illustrating a system for measuring a warpage according to an embodiment of the present invention, FIG. 4 is a diagram schematically illustrating a control unit of FIG. 3, FIG. 5 is a cross-sectional view illustrating main parts of a system for measuring a warpage according to an embodiment of the present invention, FIG. 6 is a plan view schematically illustrating a reference grating portion of the system for measuring a warpage according to the embodiment of the present invention, and FIG. 7 is a diagram for describing a principle of removing a fume of the system for measuring a warpage according to the exemplary embodiment of the present invention.

The system for measuring a warpage according to the exemplary embodiment of the present invention may measure the warpage of the sample by analyzing an image photographed by a camera acquiring light emitted from a light source and reflected from a surface of a sample and arriving through the reference grating portion.

Referring to FIGS. 3 to 7, the system 1000 for measuring a warpage according to the exemplary embodiment of the present invention may include a light source 500, a heating plate portion 300, a reference grating portion 200, a camera 400, a server 600, and a control unit 100.

First, the light source 500 serves to irradiate light to a sample 2 of which the warpage is measuring.

The light provided to the sample 2 from the light source 500 is reflected from the surface of the sample 2 and some of the reflected light reaches the camera 400 through the reference grating portion 200.

In this case, the camera 400 may be implemented by a general digital camera 400 such as a CCD camera 400, and the like, that collects light to acquire a predetermined image and outputs the acquired image in a digital data form.

The data output from the camera 400 is transferred to a server 600 and the server 600 may calculate the warpage of the same 2 by applying a shadow moiré method using a fringe image as illustrated in FIG. 2.

Meanwhile, the sample 2 may be disposed on the heating plate unit 300. In this case, the heating plate portion 300 may diffuse heat to heat the sample 2 so that the sample 2 reaches a predetermined temperature.

The reference grating portion 200 is disposed at a path through which the light reflected from the surface of the sample 2 reaches the camera 400 and may include a plurality of wires 210 that are each spaced apart from each other by a predetermined interval.

That is, the reference grating of the related art has grids formed on a transparent plate formed of quartz, and the like, at a predetermined interval, while in the system 1000 for measuring a warpage according to the exemplary embodiment of the present invention, the wires 210 are used as the grids to discharge the fume generated from the sample 2 between the plurality of wires 210.

The wires 210 may be formed to have a predetermined line width so as to serve as the grids and an interval between the respective wires 210 may also be maintained at a predetermined interval.

Further, the plurality of wires 210 may be fixed in a frame formed in various shapes.

In addition, in some cases, the interval between the wires 210 may also be changed.

Therefore, the problem of the related arts in that the reference grating is polluted due to the fume may be solved.

Meanwhile, as the heating plate portion 300 emits heat during the process of measuring the warpage of the sample 2, the temperature of the sample 2 may be increased and the temperature of the wire 210 may be increased.

In this case, when a material forming the wire 210 has a sufficiently low coefficient of thermal expansion, the phenomenon in which the wires 210 are deformed according to the increase in temperature may not be a problem.

Therefore, in the system 1000 for measuring a warpage according to the exemplary embodiment of the present invention, the wire 210 may be formed of a material having a coefficient of thermal expansion less than 15 ppm/° C.

Since the warpage of the sample 2 is currently measured ranging from 25° C. to 260° C., when the wire 210 is formed of a material having a coefficient of thermal expansion of 15 ppm/° C. or more, the reference grating may be deformed due to the reduction in tension of the wire 210, such that the image for warpage measurement may be deformed.

On the other hand, even when the wire 210 is formed of a material having a coefficient of thermal expansion of 15 ppm/° C., the tension of the wire 210 may be maintained at a constant level.

Referring to FIGS. 5 and 6, in the system 1000 for measuring a warpage according to the exemplary embodiment of the present invention, it may be understood that the reference grating portion 200 includes a first support bar 221, a second support bar 222, and a tension maintaining portion 223.

Describing in detail, the plurality of wires 210 forming the reference grating may be fixed between the first support bar 221 and the second support bar 222. That is, one end of the wire 210 may be fixed to the first support bar 221 and the other end of the wire 210 may be fixed to the second support bar 222.

Further, the first support bar 221 may be supplied with attractive force in a direction far from the second support bar 222, so that the first support bar 222 may be connected with the tension maintaining portion 223 so as to maintain the tension of the wire 210.

In this case, although not illustrated, the tension maintaining portion 223 may be implemented as an elastic member, such as a predetermined spring, and the like.

On the other hand, the tension maintaining portion 223 may also be implemented as a driving unit 225 such as a step motor, and the like.

In this case, the system 1000 for measuring a warpage includes a tension measuring portion 224 for measuring force moving the first support bar 221 in a direction of the second support bar 222, such that the tension of the wire 210 may be measured more precisely.

That is, the tension of the wire 210 may be precisely derived by measuring a stress distributed on the first support bar 221.

When the derived tension of the wire 210 falls below a reference value, the foregoing driving unit 225 may be operated.

For example, the driving unit 225 is directly connected with the tension measuring portion 224 or the tension measuring portion 224 and the driving unit 225 may each be connected with the control unit 100 to control the operation of the driving unit 225.

In this case, when the tension measuring portion 224 is directly connected with the driving unit 225, since the driving unit 225 or the tension measuring portion 224 itself may compare the reference value with the tension in real time to start the operation of the driving unit 225, a resource, such as MCU, and the like needs to be included in the driving unit 225 or the tension measuring portion 224.

On the other hand, when the tension measuring portion 224 and the driving unit 225 are connected with the control unit 100, the control of the driving unit 225 may be efficiently performed even when a separate resource is not additionally provided.

That is, as illustrated in FIG. 4, the tension control unit 120 may be included in the control unit 100 to monitor the tension measured by the tension measuring portion 224 and may compare the monitored tension with a preset reference value to generate the control signal driving the driving unit 225 when the tension is less than the reference value.

Further, as illustrated in FIG. 6, the first support bar 221 and the second support bar 222 may be fixed to a separate fixed frame 230. In this case, the second support bar 222 is completely fixed to the fixed frame 230 and the first support bar 221 may be movably coupled on the fixed frame 230. That is, the fixed frame 230 may also perform a kind of guide rail function of guiding the movement of the first support bar 221.

Meanwhile, as illustrated in FIGS. 3 and 4, the control unit 100 may further include a temperature control unit 110 and a distance control unit 120.

The temperature control unit 110 may be connected with the foregoing heating plate portion 300 to control the temperature of the heating plate portion 300.

That is, a heating element (not illustrated) such as heat rays, and the like, is included in the heating plate portion 300 and the heating element and the temperature control unit 110 are electrically connected with each other to supply electric energy, thereby increasing the temperature of the heating plate.

Further, although not illustrated, the cooling of the sample 2 is performed by spraying nitrogen, and the like, to the sample 2, thereby lowering the temperature of the sample 2.

Meanwhile, a temperature sensor (not illustrated) that is connected with the temperature control unit 110, if necessary, to measure the temperature of the sample 2 and the heating plate portion 300 may be further provided.

Next, the distance control unit 120 may be connected with the reference grating portion 200 and may serve to control a distance between the reference grating portion 200 and the heating plate portion 300.

Meanwhile, the control unit 100 is connected with the server 600 to receive a distance condition, a temperature condition, and the like, that are required for measurement.

Generally, when intending to measure the high temperature warpage for the sample 2 such as the substrate, the package, and the like, the measurement is performed by a temperature profile of 25° C.→260° C.→25° C. and the warpage data is analyzed by photographing each image in the state in which the temperature of the sample 2 is changed at an interval of 5° C. or 10° C.

Further, as an example, the warpage may be calculated by taking a photograph in the state in which the reference grating portions 200 are each disposed so that a distance between the reference grating portion 200 and the heating plate portion 300 is 100 mm, 105 mm, 110 mm, and 115 mm under the same temperature condition. In this case, a process of controlling the distance between the reference grating portion 200 and the heating plate portion 300 may be performed by the foregoing distance control unit 120.

FIG. 7 is a diagram for describing a principle of removing the fume of the system 1000 for measuring a warpage according to the exemplary embodiment of the present invention.

Referring to FIG. 7, it can be understood that the fume generated from the sample 2 is discharged between the wires 210 of the reference grating portion 200 to prevent the reference grating from being polluted.

Meanwhile, the fume starts to generate from the sample 2 or the white spray on the surface of the sample 2 from about 200° C.

The generation of the fume is more generated as the temperature of the sample 2 is increased.

FIG. 8 is a diagram schematically illustrating the fringe image acquired in the state in which the reference grating is not polluted and FIG. 9 is a diagram schematically illustrating the fringe image acquired in the state in which the reference grating is polluted.

Referring to FIGS. 8 and 9, it can be appreciated that the warpage cannot be precisely measured using only the image acquired in the state in which the reference grating is polluted due to the fume.

In this case, the fringe image of FIG. 8 may be an image photographed by the system 1000 for measuring a warpage according to the exemplary embodiment of the present invention and may be an image photographed by the general apparatus of measuring a warpage in the state in which the sample 2 is not heated, that is, in the state in which the fume is not generated and thus, the reference grating is not polluted.

As set forth above, according to the exemplary embodiments of the present invention, it is possible to measure the warpage without being affected by the fume generated from the sample according to the increase in the temperature of the sample at the time of measuring the warpage, thereby improving the accuracy of the warpage measurement.

Although the exemplary embodiments of the present invention have been disclosed for illustrative purposes, those skilled in the art will appreciate that various modifications, additions, and substitutions are possible, without departing from the scope and spirit of the invention as disclosed in the accompanying claims. Accordingly, such modifications, additions, and substitutions should also be understood to fall within the scope of the present invention.

What is claimed is:

1. A system of measuring a warpage of a sample by analyzing an image photographed by a camera acquiring light emitted from a light source and reflected from a surface of the sample and arriving through a reference grating portion, the system comprising:
a heating plate portion heating the sample; and
a reference gating portion disposed between the sample and the camera so as to be spaced apart from the sample by a predetermined distance,
wherein the reference grating portion includes a plurality of wires that are each spaced apart from each other by a predetermined interval.

2. The system according to claim 1, wherein the reference grating portion includes:
a first support bar to which ends of the plurality of wires are fixed; and
a second support bar to which other ends of the plurality of wires are fixed, and
the first support bar is connected with a tension maintaining portion maintaining a tension of the plurality of wires.

3. The system according to claim 2, wherein the tension maintaining portion includes a driving unit providing attractive force to the first support bar.

4. The system according to claim 3, wherein the tension maintaining portion further includes:
a tension measuring portion coupled with the first support bar and measuring force moving the first support bar in a direction of the second support bar, and
the driving unit is connected with the tension measuring portion to start to drive when the tension measured by the tension measuring portion is less than a reference value.

5. The system according to claim 2, wherein the tension maintaining portion is a spring.

6. The system according to claim 1, wherein the plurality of wires are formed of a material having a coefficient of thermal expansion less than 15 ppm/° C.

7. A system for measuring a warpage, comprising:
a light source irradiating light to be reflected from a surface of a sample of which the warpage is measured;
a heating plate portion having the sample disposed thereon and emitting heat;
a reference grating portion spaced apart from the sample by a predetermined distance and transmitting light reflected from the surface of the sample;
a camera acquiring light transmitting the reference grating portion to photograph an image;
a server analyzing the image photographed by the camera to calculate the warpage of the sample; and
a control unit provided with an intake portion removing a fume generated from the sample,
wherein the reference grating portion includes a plurality of wires that are each spaced apart from each other by a predetermined interval.

8. The system according to claim 7, wherein the reference grating portion further includes:
a first support bar to which ends of the plurality of wires are fixed;
a second support bar to which other ends of the plurality of wires are fixed; and
a driving unit providing attractive force to the first support bar.

9. The system according to claim 8, wherein the reference grating portion further includes:
a tension measuring portion coupled with the first support bar and measuring force moving the first support bar in a direction of the second support bar, and
the driving unit is connected with the tension measuring portion to start to drive when the tension measured by the tension measuring portion is less than a reference value.

10. The system according to claim 8, wherein the reference grating portion further includes:
a tension measuring portion coupled with the first support bar to measure force moving the first support bar in a direction of the second support bar and provide the measured force to the control unit, and
the control unit includes a tension control unit that is connected with the driving unit to generate a control signal driving the driving unit when the tension measured by the tension measuring portion is less than a reference value.

11. The system according to claim 7, wherein the control unit further includes a temperature control unit that is connected with the heating plate portion to control a temperature of the heating plate portion.

12. The system according to claim 7, wherein the control unit further includes:
a distance control unit connected with the reference grating portion to control a distance between the reference grating portion and the heating plate portion.

13. A method for measuring a warpage of a sample by analyzing an image photographed by a camera acquiring light emitted from a light source and reflected from a surface of a sample and transmitting between a plurality of wires spaced apart from each other by a predetermined interval, wherein the image is photographed while a tension of the plurality of wires is maintained above a predetermined reference value.
